(19) United States
(12) Patent Application Publication
(10) Pub. No.: US 2025/0307506 A1
(43) Pub. Date: Oct. 2, 2025

(54) CALCULATION METHOD AND APPARATUS OF RUNOFF POLLUTION LOAD, ELECTRONIC DEVICE AND STORAGE MEDIUM

(71) Applicants: CTG Logistics Management (Beijing) Co., Ltd., Beijing (CN); China Three Gorges Corporation, Hubei (CN)

(72) Inventors: Yasong CHEN, Beijing (CN); Dianchang WANG, Beijing (CN); Yating ZHU, Beijing (CN); Yunpeng ZHAO, Beijing (CN); Manqi CHANG, Beijing (CN); Zhonglin NIE, Beijing (CN); Fangyuan JING, Beijing (CN); Chong LI, Beijing (CN)

(21) Appl. No.: 19/201,352

(22) Filed: May 7, 2025

Related U.S. Application Data
(63) Continuation of application No. PCT/CN2024/116957, filed on Sep. 4, 2024.

(30) Foreign Application Priority Data
Mar. 27, 2024 (CN) 202410355775.4

(51) Int. Cl. G06F 30/28

(52) U.S. Cl. CPC G06F 30/28

(57) ABSTRACT

The present application provides a calculation method of a runoff pollution load, including: determining a target discharge outlet of a to-be-calculated runoff pollution load in a target area; for any sub-catchment area corresponding to the target discharge outlet, obtaining a load characteristic factor corresponding to a current sub-catchment area and a characteristic coefficient corresponding to the load characteristic factor when calculating the runoff pollution load based on the load characteristic factor; determining a runoff pollution load of the current sub-catchment area based on the load characteristic factor and the characteristic coefficient; determining a sum of runoff pollution loads of respective sub-catchment areas corresponding to the target discharge outlet, and performing a correction processing on the sum of runoff pollution loads based on a time correction factor between a target year and the preset year, to determine a target runoff pollution load of the target discharge outlet in the target year.

### CROSS-REFERENCE TO RELATED APPLICATIONS

The present application is a continuation of International Application No. PCT/CN2024/116957, filed on Sep. 4, 2024, which claims priority to Chinese Patent Application No. 202410355775.4, filed with the China National Intellectual Property Administration on Mar. 27, 2024 and titled “CALCULATION METHOD AND APPARATUS OF RUNOFF POLLUTION LOAD, ELECTRONIC DEVICE AND STORAGE MEDIUM”. The applications are hereby incorporated by reference in their entireties.

### TECHNICAL FIELD

The present application relates to a field of urban water environment treatment technologies, and in particular to a calculation method and apparatus of a runoff pollution load, an electronic device and a storage medium.

### BACKGROUND

With the effective control of urban point source pollution, the impact of non-point source pollution on urban water environment is becoming increasingly prominent. Rainfall-induced surface runoff pollution, as an important non-point source pollution source in urban areas, has the characteristics of uncertain occurrence, significant influence of environmental factors on discharge and migration, so the calculation of its pollution load is relatively complex.

At present, the method for calculating the pollution load of the surface runoff mainly adopts a statistical model method, and specifically the calculation of the load involves analyzing a large number of actually measured data to explore the correlation between the pollution load and the influencing factors and construct empirical formulas or functional equations, and then using the actual monitoring data to achieve the load calculation.

However, due to the seasonality and randomness of rainfall each year, it is difficult to ensure the timeliness and accuracy of current algorithms in calculating runoff pollution load.

### SUMMARY

An object of the present application is to provide a calculation method and apparatus of a runoff pollution load, an electronic device, and a storage medium, to solve the problems of low accuracy and timeliness in the calculation of the runoff pollution load in the related art, and to improve the efficiency and accuracy of the calculation result of the runoff pollution load.

In a first aspect, the present application discloses a calculation method of a runoff pollution load, including:
determining a target discharge outlet of a to-be-calculated runoff pollution load in a target area, where the target area is consisting of a plurality of feature areas with different area related features, the feature area is consisting of a plurality of sub-catchment areas, the target area includes a plurality of discharge outlets, and each discharge outlet collects runoff pollution loads from different sub-catchment areas;
for any sub-catchment area corresponding to the target discharge outlet, obtaining a load characteristic factor corresponding to a current sub-catchment area and a characteristic coefficient corresponding to the load characteristic factor when calculating the runoff pollution load based on the load characteristic factor, where the load characteristic factor is a factor that affects a pollution load formed when a runoff pollutant of each sub-catchment area converges at a catchment outlet, and the characteristic coefficient is determined based on the load characteristic factors respectively corresponding to a plurality of preset sub-catchment areas in the target area and a runoff pollution load equivalent in a preset year;
determining a runoff pollution load of the current sub-catchment area in the preset year based on the load characteristic factor and the characteristic coefficient; and
determining a sum of runoff pollution loads of respective sub-catchment areas corresponding to the target discharge outlet in the preset year, and performing a correction processing on the sum of runoff pollution loads based on a time correction factor between a target year and the preset year, to determine a target runoff pollution load corresponding to the target discharge outlet in the target year.

In the above technical contents, by a benchmark runoff pollution load equivalent of a pre-selected benchmark catchment area in a target area in a preset year, a load characteristic factor that affects a pollution load formed when a runoff pollutant converges at a catchment outlet of a sub-catchment area and a corresponding characteristic coefficient are determined, and thus quick calculation of the runoff pollution load of each catchment area, and then quick calculation of the runoff pollution load of the target discharge outlet in the target area are achieved. This avoids the technical problems that it is difficult to achieve the timeliness and accuracy requirements of the fast calculation for the calculation result due to a large amount of monitoring data, repeated monitoring, large error of monitoring randomness, and long cycle of load calculation, etc.; and this achieves improvement of the efficiency and accuracy of the calculation result of the runoff pollution load.

In another possible implementation, before determining the target discharge outlet of the to-be-calculated runoff pollution load in the target area, the method further includes:
obtaining area related feature data that affects the runoff pollution load in different areas in the target area, and performing a functional area division on the target area based on the area related feature data to obtain a plurality of feature areas corresponding to the target area; and
for any feature area, performing a catchment area division on a current feature area based on a rainfall catchment range to obtain a plurality of sub-catchment areas corresponding to the current feature area.

In another possible implementation, the feature area includes a benchmark sub-catchment area and other sub-catchment areas;
correspondingly, determining the characteristic coefficient based on the load characteristic factors respectively corresponding to the plurality of preset sub-catchment areas in the target area and the runoff pollution load equivalent in the preset year includes:
for any feature area, determining the benchmark sub-catchment area in a current feature area, obtaining runoff pollution monitoring data of the benchmark sub-catchment area in the preset year, and determining a benchmark runoff pollution load equivalent of the benchmark sub-catchment area in the preset year based on the runoff pollution monitoring data; and
obtaining a benchmark load characteristic factor of each benchmark sub-catchment area corresponding to each feature area, and based on each benchmark load characteristic factor and each benchmark runoff pollution load equivalent, determining the characteristic coefficient corresponding to the load characteristic factor when calculating the runoff pollution load based on the load characteristic factor.

In another possible implementation, determining the benchmark runoff pollution load equivalent of the benchmark sub-catchment area in the preset year based on the runoff pollution monitoring data includes:
obtaining a preset runoff pollution load statistical algorithm, and determining a benchmark runoff pollution load of the benchmark sub-catchment area based on the runoff pollution load statistical algorithm and the runoff pollution monitoring data; and
performing a statistical processing of runoff pollution load per unit area on the benchmark runoff pollution load, to determine the benchmark runoff pollution load equivalent corresponding to the benchmark sub-catchment area in the preset year.

In another possible implementation, based on each benchmark load characteristic factor and each benchmark runoff pollution load equivalent, determining the characteristic coefficient corresponding to the load characteristic factor when calculating the runoff pollution load based on the load characteristic factor includes:
for any feature area, establishing a load-factor relationship equation between the benchmark load characteristic factor and the benchmark runoff pollution load equivalent in current feature area; and
constructing a system of load-factor relationship equations based on the load-factor relationship equations corresponding to respective feature areas, and determining the characteristic coefficient based on a preset coefficient correlation between the system of load-factor relationship equations and each characteristic coefficient.

In another possible implementation, the load characteristic factor includes a road square proportion, a building roof proportion, a green space proportion, a water surface wetland proportion and a terrain slope factor;
correspondingly, the load-factor relationship equation includes:

$${S}_{i} = {K}_{pi} \times ( {k}_{1 i} {A}_{i} + {k}_{2 i} {B}_{i} + {k}_{3 i} {C}_{i} + {k}_{4 i} {D}_{i} ) ;$$

where Sᵢ represents the benchmark runoff pollution load equivalent of the benchmark sub-catchment area in any feature area; Aᵢ represents the road square proportion; Bᵢ represents the building roof proportion; Cᵢ represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.

In another possible implementation, the coefficient correlation includes: the characteristic coefficients corresponding to the building roof proportion in different feature areas are equal; the characteristic coefficients corresponding to the water surface wetland proportion in different feature areas are equal; and there is a preset proportional relationship between the characteristic coefficient corresponding to the green space proportion and the characteristic coefficient corresponding to the road square proportion in the same feature area.

In a second aspect, the present application provides a calculation apparatus of a runoff pollution load, including:
a target discharge outlet determination module, configured to determine a target discharge outlet of a to-be-calculated runoff pollution load in a target area, where the target area is consisting of a plurality of feature areas with different area related features, the feature area is consisting of a plurality of sub-catchment areas, and the target area includes a plurality of discharge outlets, and each discharge outlet collects runoff pollution loads from different sub-catchment areas;
a data obtaining module, configured to, for any sub-catchment area corresponding to the target discharge outlet, obtain a load characteristic factor corresponding to a current sub-catchment area and a characteristic coefficient corresponding to the load characteristic factor when calculating the runoff pollution load based on the load characteristic factor, where the load characteristic factor is a factor that affects a pollution load formed when a runoff pollutant of each sub-catchment area converges at a catchment outlet, the characteristic coefficient is determined based on the load characteristic factors respectively corresponding to a plurality of preset sub-catchment areas in the target area and a runoff pollution load equivalent in a preset year;
a runoff pollution load determination module, configured to determine a runoff pollution load of the current sub-catchment area in the preset year based on the load characteristic factor and the characteristic coefficient; and
a target runoff pollution load determination module, configured to determine a sum of runoff pollution loads of respective sub-catchment areas corresponding to the target discharge outlet in the preset year, and perform a correction processing on the sum of runoff pollution loads based on a time correction factor between a target year and the preset year, to determine a target runoff pollution load corresponding to the target discharge outlet in the target year.

In another possible implementation, the apparatus further includes:
a feature area determination unit, configured to, before determining the target discharge outlet of the to-be-calculated runoff pollution load in the target area, obtain area related feature data that affects the runoff pollution load in different areas in the target area, and perform a functional area division on the target area based on the area related feature data to obtain a plurality of feature areas corresponding to the target area; and
a sub-catchment area determination unit, configured to, for any feature area, perform a catchment area division on a current feature area based on a rainfall catchment range to obtain a plurality of sub-catchment areas corresponding to the current feature area.

In another possible implementation, the feature area includes a benchmark sub-catchment area and other sub-catchment areas;
correspondingly, the data obtaining module includes:
a benchmark runoff pollution load equivalent determination sub-module, configured to, for any feature area, determine the benchmark sub-catchment area in a current feature area, obtain runoff pollution monitoring data of the benchmark sub-catchment area in the preset year, and determine a benchmark runoff pollution load equivalent of the benchmark sub-catchment area in the preset year based on the runoff pollution monitoring data; and
a characteristic coefficient determination sub-module, configured to obtain a benchmark load characteristic factor of each benchmark sub-catchment area corresponding to each feature area, and based on each benchmark load characteristic factor and each benchmark runoff pollution load equivalent, determine the characteristic coefficient based on the load characteristic factor.

In another possible implementation, the benchmark runoff pollution load equivalent determination sub-module includes:
a benchmark runoff pollution load equivalent determination unit, configured to obtain a preset runoff pollution load statistical algorithm, and perform a statistical processing on runoff pollution load per unit area of the benchmark sub-catchment area based on the runoff pollution load statistical algorithm and the runoff pollution monitoring data, to determine a benchmark runoff pollution load equivalent corresponding to the benchmark sub-catchment area in the preset year.

In another possible implementation, the characteristic coefficient determination sub-module includes:
a load-factor relationship equation determination unit, configured to, for any feature area, establish a load-factor relationship equation between the benchmark load characteristic factor and the benchmark runoff pollution load equivalent in the current feature area; and
a characteristic coefficient determination unit, configured to construct a system of load-factor relationship equations based on the load-factor relationship equations respectively corresponding to the feature areas, and determine the characteristic coefficient based on a preset coefficient correlation between the system of load-factor relationship equations and each characteristic coefficient.

In another possible implementation, the load characteristic factor includes a road square proportion, a building roof proportion, a green space proportion, a water surface wetland proportion and a terrain slope factor;
correspondingly, the load-factor relationship equation includes:

Sᵢ=Kₚᵢ×(k₁ᵢAᵢ+k₂ᵢBᵢ+k₃ᵢCᵢ+k₄ᵢDᵢ);
where Sᵢ represents the benchmark runoff pollution load equivalent of the benchmark sub-catchment area in any feature area; Aᵢ represents the road square proportion; Bᵢ represents the building roof proportion; Cᵢ represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.

In another possible implementation, the coefficient correlation includes: the characteristic coefficients corresponding to the building roof proportion in different feature areas are equal; the characteristic coefficients corresponding to the water surface wetland proportion in different feature areas are equal; and there is a preset proportional relationship between the characteristic coefficient corresponding to the green space proportion and the characteristic coefficient corresponding to the road square proportion in the same feature area.

In a third aspect, the present application provides an electronic device, including: a processor and a memory connected in communication with the processor; where
the memory stores computer-executable instructions; and
the processor executes the computer-executable instructions stored in the memory to implement the method as described in the first aspect.

In a fourth aspect, the present application provides a computer-readable storage medium, storing computer-executable instructions which, when executed by a processor, are used to implement the method as described in the first aspect.

In a fifth aspect, the present application provides a computer program product, including a computer program which, when executed by a processor, implements the method as described in the first aspect.

In the technical solutions provided in the present application, by using a benchmark runoff pollution load equivalent of a pre-selected benchmark catchment area in a target area in a preset year, a load characteristic factor that affects a pollution load formed when a runoff pollutant of each sub-catchment area converging at a catchment outlet and a corresponding characteristic coefficient are determined, and thus quick calculation of the runoff pollution load of each sub-catchment area, and then quick calculation of the runoff pollution load of the target discharge outlet in the target area are achieved. This avoids the technical problems that it is difficult to achieve the timeliness and accuracy requirements of the fast calculation for the calculation result due to a large amount of monitoring data, repeated monitoring, large error of monitoring randomness, and long cycle of load calculation, etc.; and this achieves improvement of the efficiency and accuracy of the calculation result of the runoff pollution load.

### BRIEF DESCRIPTION OF DRAWINGS

Accompanying drawings herein, which are incorporated into the specification and constitute a part of the specification, show embodiments in accordance with the present application, and are used together with the specification to explain the principle of the present application.

FIG. 1 is an application scenario diagram of a calculation method of a runoff pollution load provided in the present application.

FIG. 2 is a schematic flowchart of a calculation method of a runoff pollution load provided in an embodiment of the present application.

FIG. 3 is a schematic structural diagram of a calculation apparatus of a runoff pollution load provided in an embodiment of the present application.

FIG. 4 is a schematic structural diagram of an electronic device provided in an embodiment of the present application.

FIG. 5 is a block diagram of a terminal electronic device illustrated in an embodiment of the present application.

The specific embodiments of the present application have been illustrated by the above accompanying drawings, and will be described in more detail below. These accompanying drawings and literal descriptions are not intended to limit the scope of the concept of the present application in any way, but to explain the concept of the present application to those skilled in the art by referring to specific embodiments.

### DESCRIPTION OF EMBODIMENTS

Illustrative embodiments will be described in detail herein, examples of which are shown in the accompanying drawings. When the following description refers to the drawings, unless otherwise indicated, the same numbers in different drawings indicate the same or similar elements. Implementations described in the following illustrative embodiments do not represent all embodiments consistent with the present application. On the contrary, they are merely examples of apparatus and methods consistent with some aspects of the present application as detailed in the appended claims.

In related technologies, the runoff pollution load is generally calculated through exploring the correlation between pollution load and various influence factors and constructing empirical formulas or functional equations, so as to determine the runoff pollution load; for example, a pollution load equivalent method is used to calculate the runoff pollution load. However, the above method requires a large amount of actual monitoring data. At least 15-20 rainfall runoff measurements are required for sub-catchment areas included in a target discharge outlet to obtain a weighted average concentration of pollutants that relatively accurately represents the pollution situation of the runoff, and then the runoff pollution load of the target discharge outlet is calculated. This exists problems such as a large amount of monitoring data, repeated monitoring, large error of monitoring randomness, and long cycle of load calculation, etc., which in turn make it difficult to achieve the timeliness and accuracy requirements of fast calculation for the calculation result.

The calculation method of a runoff pollution load provided in the present application aims to solve the above-mentioned technical problems in the related art. Specifically, by using a benchmark runoff pollution load equivalent of a pre-selected benchmark catchment area in a target area in a preset year, a load characteristic factor that affects a pollution load formed when a runoff pollutant converges at a catchment outlet of a sub-catchment area and a corresponding characteristic coefficient are determined, and thus quick calculation of the runoff pollution load of each catchment area, and then quick calculation of the runoff pollution load of the target discharge outlet in the target area are achieved. This avoids the technical problems that it is difficult to achieve the timeliness and accuracy requirements of fast calculation for the calculation result due to a large amount of monitoring data, repeated monitoring, large error of monitoring randomness, and long cycle of load calculation, etc.; and this achieves the improvement of the efficiency and accuracy of the calculation result of the runoff pollution load.

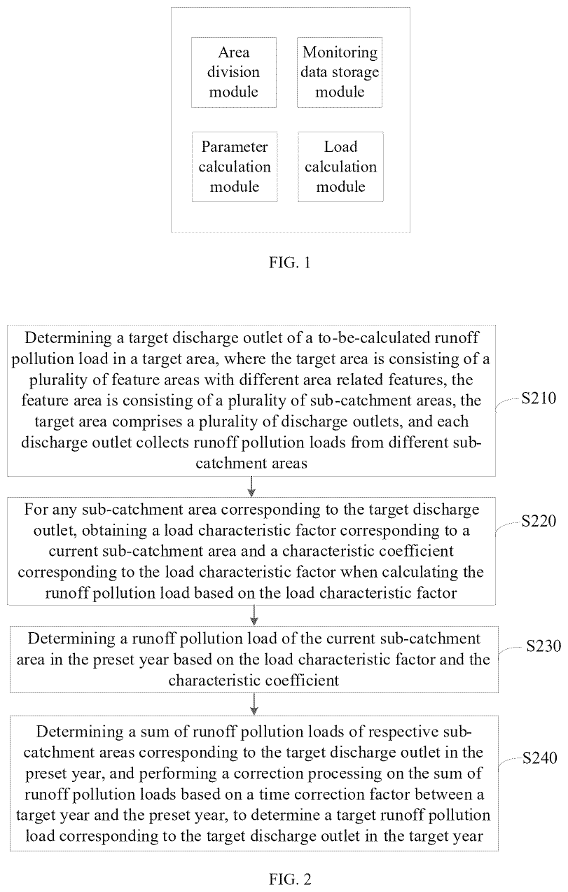

FIG. 1 is an application scenario diagram of a calculation method of a runoff pollution load provided in the present application. For ease of understanding, an application scenario applicable to an embodiment of the present application will be explained below in conjunction with FIG. 1. Referring to FIG. 1, the above calculation method of the runoff pollution load can be applied to a preset load accounting system. The system can include an area division module, a monitoring data storage module, a parameter calculation module, and a load calculation module; where the area division module is configured to perform multi-level region division on a target area, to determine feature areas contained in the target area, as well as benchmark sub-catchment areas and other sub-catchment areas contained in the feature areas, and determine a sub-catchment area corresponding to a target discharge outlet in the target area; the monitoring data storage module is configured to store pollution monitoring data obtained in a preset year from a plurality of times monitoring of the catchment outlet of the benchmark sub-catchment area in each feature area of the target area; the parameter calculation module is configured to calculate a benchmark runoff pollution load equivalent of each benchmark sub-catchment area in the preset year based on the pollution monitoring data, establish a system of load-factor relationship equations based on the benchmark runoff pollution load equivalent of each benchmark sub-catchment area in each feature area and the load characteristic factor of each benchmark catchment outlet, and solve equation relationship to obtain a characteristic coefficient corresponding to each load characteristic factor; and the load calculation module is configured to determine a runoff pollution load of each catchment area based on a load characteristic factor of and a corresponding characteristic coefficient of each catchment area corresponding to the target discharge outlet, so as to quickly calculate target runoff pollution load of the target discharge outlet in the target area based on each runoff pollution load.

It can be explained that although various modules and their logical order are shown in the scenario diagram, in some cases, the technical solution shown or described may be executed in a different module and logical order than those given here.

The technical solutions of the present application and how the technical solutions of the present application solve the above technical problems are described in detail below by way of specific embodiments. The following specific embodiments may be combined with each other, and the same or similar concepts or processes may not be repeated in certain embodiments. Embodiments of the present application will be described below in conjunction with the accompanying drawings.

FIG. 2 is a schematic flowchart of a calculation method of a runoff pollution load provided in an embodiment of the present application. The method can be executed by a calculation apparatus of a runoff pollution load, and the calculation apparatus can be a server or an electronic device. Taking the electronic device as an example, the method in this embodiment can be implemented through software, hardware, or a combination of software and hardware. As shown in FIG. 2, the method includes the following steps.

S210, determining a target discharge outlet of a to-be-calculated runoff pollution load in a target area; where the target area is consisting of a plurality of feature areas with different area related features; the feature area is consisting of a plurality of sub-catchment areas; and the target area includes a plurality of discharge outlets, and each discharge outlet collects runoff pollution loads from different sub-catchment areas.

In an embodiment of the present application, the target area can be understood as any area with surface runoff pollution. Exemplarily, the target area could be an urban built-up area of a city in middle and lower reaches of the Yangtze River Basin. Since the scope of the target area is large, and different locations in an area possess different characteristics, resulting in different load statistical results of runoff pollution in different locations of the target area. Therefore, in related technologies, the target area can be divided into a plurality of feature areas. Furthermore, in order to facilitate rapid and accurate statistics of pollution load, the feature area is further divided into a plurality of sub-catchment areas. It can be explained that due to a geographical characteristic, there are a plurality of discharge outlets in the target area to discharge surface runoff pollution, and each discharge outlet collects runoff pollution loads from different sub-catchment areas.

In related technologies, in order to quickly and accurately calculate the target runoff pollution load corresponding to the target discharge outlet in the target area, in an embodiment of the present application, the target area are divided into a plurality of feature areas according to the area related feature of the area.

In an implementation, a process of obtaining the feature area in the present application may specifically include: obtaining area related feature data that affects the runoff pollution loads within different areas in the target area, and performing a functional area division on the target area based on the area related feature data to obtain a plurality of feature areas corresponding to the target area.

In related technologies, the area related feature that affects the runoff pollution load within different areas can include but is not limited to: any one or more of a functional characteristic of a built-up area, a population density, a coverage rate of a rainwater pipe network, terrain, and per capita GDP.

Specifically, the target area can be divided into a plurality of feature areas according to the distribution of population density and of human activity characteristics on the underlying surface of the target area; specifically, the target area can also be divided into a plurality of feature areas according to the coverage rate of the rainwater pipe network of the target area or the terrain of the target area. Certainly, the target area can also be divided according to other features to obtain feature areas. The specific condition for dividing to obtain the feature areas is not limited in the embodiment of the present application.

Exemplarily, the technical solution of the present application may include several (≤4) feature areas in the target area; for example, a core commercial area, a residential area, an industrial cluster area, and a low impact development area.

In an embodiment of the present application, the sub-catchment area can be understood as a plurality of sub-areas obtained by further dividing the feature area. Specifically, the above-mentioned feature area can also be understood as a plurality of catchment areas divided from the target area. However, in related technologies, when the catchment area is too large or too small, the calculation result of the runoff pollution load has a relatively low reliability when used as the basis for subsequent engineering management. Therefore, on the basis of obtaining a plurality of feature areas contained in the target area, each feature area is further divided to obtain a plurality of sub-catchment areas contained in each feature area.

In an implementation, a process of obtaining the sub-catchment areas in the present application may specifically include: performing an area division on a current feature area based on a rainfall catchment range to obtain a plurality of sub-catchment areas corresponding to the current feature area.

In related technologies, taking any feature area as an example, the area division is performed on water basin scope of the feature area according to the rainfall catchment range of the feature area, to at least one sub-catchment area of the feature area.

For example, in order to quickly calculate the runoff pollution load based on the sub-catchment areas and ensure high reliability of the calculation result, an area of the sub-catchment area in the present application should be controlled within 2-3 km².

On this basis, based on the geographical characteristic of the target area, the sub-catchment areas respectively corresponding to the discharge outlets in the target area are counted, that is, for any discharge outlet, it is determined which sub-catchment area in the target area will collect its runoff pollutant to current discharge outlet and discharge the runoff pollutant based on the current discharge outlet. Furthermore, a mapping table of a correspondence between each discharge outlet and the catchment area is formed, so that when calculating the runoff pollution load of any discharge outlet as the target discharge outlet in the target area, a plurality of corresponding sub-catchment areas can be quickly determined first, and then the runoff pollution load of the target discharge outlet can be obtained by calculating the runoff pollution loads of the sub-catchment areas.

S220, for any sub-catchment area corresponding to the target discharge outlet, obtaining a load characteristic factor corresponding to a current sub-catchment area and a characteristic coefficient corresponding to the load characteristic factor when calculating the runoff pollution load based on the load characteristic factor.

In an embodiment of the present application, the load characteristic factor can be understood as a factor that affects a pollution load formed when a runoff pollutant of each sub-catchment area converges at a catchment outlet; and the characteristic coefficient can be understood as a calculation parameter that characterizes the differences in runoff pollution loads of sub-catchment areas of different feature areas. Specifically, the characteristic coefficient is determined based on load characteristic factors respectively corresponding to a plurality of preset sub-catchment areas in the target area and a runoff pollution load equivalent in a preset year.

It can be explained that the runoff pollution load equivalent can be understood as a pollution load corresponding to per unit area in a preset sub-catchment area; that is, when determining the runoff pollution load equivalent, the runoff pollution load collected in the sub-catchment area needs to be determined in advance, and the runoff pollution load equivalent of the sub-catchment area is then determined based on the runoff pollution load and the area of the sub-catchment area.

It can also be explained that for any sub-catchment area, the sub-catchment areas in the feature area are divided into a benchmark sub-catchment area and a plurality of other sub-catchment areas. It can be explained that, taking any feature area as an example, the benchmark sub-catchment area can be any sub-catchment area randomly selected in the current feature area; certainly, in order to facilitate subsequent parameter calculations, the benchmark sub-catchment area in related technologies is a sub-catchment area with a strong area correlation with other sub-catchment areas in the current feature area. Specifically, the correlation between the sub-catchment areas can be calculated based on the area related features of the sub-catchment areas, and then a sub-catchment area with the highest area correlation with the sub-catchment areas can be obtained, and this sub-catchment area can be determined as the benchmark sub-catchment area in the current feature area.

On this basis, a calculation process of the characteristic coefficient in the embodiments of the present application may specifically include: for any feature area, determining the benchmark sub-catchment area in a current feature area, obtaining runoff pollution monitoring data of the benchmark sub-catchment area in a preset year, and determining a benchmark runoff pollution load equivalent of the benchmark sub-catchment area in the preset year based on the runoff pollution monitoring data; obtaining a benchmark load characteristic factor of each benchmark sub-catchment area corresponding to each feature area, and based on each benchmark load characteristic factor and each benchmark runoff pollution load equivalent, determining the characteristic coefficient based on the load characteristic factor.

It can be explained that the above calculation of the load characteristic factor can achieve determining the difference between different sub-catchment areas by mining common factor and characteristic factor existing in different sub-catchment areas, and then calculating the runoff pollution loads of a small number of sub-catchment areas, and obtaining the runoff pollution loads of other sub-catchment areas through correcting the calculated runoff pollution load based on the difference, so that the target runoff pollution load corresponding to the target area can be quickly obtained.

Specifically, in the embodiment of the present application, to calculate the characteristic coefficient, it is necessary to determine in advance the benchmark runoff pollution load equivalent of the benchmark sub-catchment area in each feature area in the preset year, as well as the load characteristic factor corresponding to each benchmark sub-catchment area; and then, a system of relationship equations is constructed for the above two parameters, and the characteristic coefficient is determined based on the solution result of the system of the equations.

It can be explained that the preset year can be understood as any selected year in the embodiment of the present application, including but not limited to current year or other years before the current year that meet a preset rainfall condition.

In an implementation, a specific process of determining the benchmark runoff pollution load equivalent in the embodiment of the present application may include: obtaining a preset runoff pollution load statistical algorithm, and determining a benchmark runoff pollution load of the benchmark sub-catchment area based on the runoff pollution load statistical algorithm and the runoff pollution monitoring data; and performing a statistical processing of runoff pollution load per unit area on the benchmark runoff pollution load, to determine the benchmark runoff pollution load equivalent corresponding to the benchmark sub-catchment area in the preset year.

In an embodiment of the present application, the runoff pollution monitoring data can be understood as monitoring data obtained from each of 10-15 times of pollutant monitoring conducted at the benchmark catchment outlet corresponding to the benchmark sub-catchment area in the preset year. Exemplarily, the runoff pollution monitoring data includes but is not limited to data such as rainfall runoff volume, and pollutant concentration.

Exemplarily, a formula for calculating the benchmark runoff pollution load can be:

$$La = {C}_{F} \times Ψ \times A \times P \times C \times 0.01 ;$$

where La represents the benchmark runoff pollution load of the benchmark sub-catchment area; CF represents a correction factor for rainfall that does not generate surface runoff (a proportion of rainfall events that generate runoff to total rainfall events), usually taken as 0.9; Ψ represents an average runoff coefficient of a plurality of sub-catchment areas; A represents a catchment area of the benchmark sub-catchment area; P represents an annual rainfall in a preset year; C represents an average pollutant concentration at the benchmark catchment outlet in the preset year obtained by statistical analysis of monitoring data from 10 to 15 times of monitored rainfall events.

Specifically, the obtained runoff pollution monitoring data is put into the above calculation formula to obtain the benchmark runoff pollution load of the benchmark sub-catchment area in each feature area in the preset year.

Exemplarily, in this embodiment, COD (Chemical Oxygen Demand) is used as a representative pollution indicator for calculation of pollution load. Parameters of the benchmark runoff pollution loads corresponding to the benchmark catchment outlets of the benchmark sub-catchment areas of four feature areas in the target area are shown in the table below:

TABLE 1
Parameters table of benchmark runoff pollution loads

| | Benchmark | | | A | P | C |
|---|---|---|---|---|---|---|
| Feature area | catchment outlet | C_{F} | Ψ | (hm²) | (mm) | (mg/L) |
| Core | 1 | 0.9 | 0.65 | 236 | 1532 | 186.3 |
| commercial area | | | | | | |
| Residential area | 2 | 0.9 | 0.6 | 274 | 1532 | 196.7 |
| Industrial | 3 | 0.9 | 0.7 | 218 | 1532 | 125.8 |
| cluster area | | | | | | |
| Low impact | 4 | 0.9 | 0.3 | 238 | 1532 | 94.2 |
| development area | | | | | | |

When only monitoring the data of the benchmark catchment outlet in the feature area as mentioned above, due to relatively small amount of monitored data and consistent sampling and monitoring methods for different areas, the monitoring error is reduced and the data accuracy is improved, thereby ensuring the accuracy of calculation of the pollution load.

Furthermore, the statistical processing of runoff pollution load per unit area is performed on the benchmark runoff pollution load of the benchmark sub-catchment area, to determine the benchmark runoff pollution load equivalent corresponding to the benchmark sub-catchment area in the preset year. Specifically, the manner for performing statistical processing of runoff pollution load per unit area specifically can be dividing the benchmark runoff pollution load of any benchmark sub-catchment area by the area corresponding to this benchmark sub-catchment area, thereby obtaining the benchmark runoff pollution load equivalent corresponding to the benchmark sub-catchment area in the preset year.

Exemplarily, an expression for processing per unit area can be:

$$S = \frac{La}{Ms} ;$$

where S represents the benchmark runoff pollution load equivalent of the benchmark sub-catchment area; La represents the benchmark runoff pollution load of the benchmark sub-catchment area; and Mₛ represents the area of the benchmark sub-catchment area.

In an embodiment of the present application, on basis of calculating the benchmark runoff pollution load equivalent corresponding to the benchmark sub-catchment area in each feature area in the preset year, the load characteristic factor of each feature area is obtained, and then a system of equations is constructed based on each benchmark runoff pollution load equivalent and each load characteristic factor, and the system of equations is solved to obtain the characteristic coefficient.

In an implementation, a process of obtaining the characteristic coefficient as described above can specifically include: for any feature area, establishing a load-factor relationship equation between the benchmark load characteristic factor and the benchmark runoff pollution load equivalent in the current feature area; and constructing a system of load-factor relationship equations based on the load-factor relationship equations corresponding to respective feature areas, and determining the characteristic coefficient based on a preset coefficient correlation between the system of load-factor relationship equations and respective characteristic coefficients.

In related technologies, since the rainfall characteristics, pollution deposition characteristics, and economic and social activities are basically the same in the same city or region, the calculation of the runoff pollution load is less affected by the above factors. Moreover, since the areas of sub-catchment areas are 2-3 km², the calculation of the runoff pollution load is also less affected by pipe network convergence. Therefore, the load characteristic factor in calculating the runoff pollution load mainly includes: a road square proportion, a building roof proportion, a green space proportion, a water surface wetland proportion and a terrain slope factor.

On the basis of the above, for any feature area, the load-factor relationship equation between the benchmark load characteristic factor and the benchmark runoff pollution load equivalent is constructed. Exemplarily, a specific equation expression can be:

$${S}_{i} = {K}_{pi} \times ( {k}_{1 i} {A}_{i} + {k}_{2 i} {B}_{i} + {k}_{3 i} {C}_{i} + {k}_{4 i} {D}_{i} ) ;$$

where Sᵢ represents the benchmark runoff pollution load equivalent of the benchmark sub-catchment area in any feature area; Aᵢ represents the road square proportion; Bᵢ represents the building roof proportion; Ci represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.

Furthermore, the equation expressions of the load-factor relationship equations corresponding to four feature areas obtained based on the above area dividing manner are calculated, and combining the four equation expressions to obtain a system of load-factor relationship equations. Exemplarily, the system of the equations specifically can be:

$${S}_{1} = {K}_{p 1} \times ( {k}_{11} {A}_{1} + {k}_{21} {B}_{1} + {k}_{31} {C}_{1} + {k}_{41} {D}_{1} ) ;$$

$${S}_{2} = {K}_{p 2} \times ( {k}_{12} {A}_{2} + {k}_{22} {B}_{2} + {k}_{32} {C}_{2} + {k}_{42} {D}_{2} ) ;$$

$${S}_{3} = {K}_{p 3} \times ( {k}_{13} {A}_{3} + {k}_{23} {B}_{3} + {k}_{33} {C}_{3} + {k}_{43} {D}_{3} ) ;$$

$${S}_{4} = {K}_{p 4} \times ( {k}_{14} {A}_{4} + {k}_{24} {B}_{4} + {k}_{34} {C}_{4} + {k}_{44} {D}_{4} ) .$$

On this basis, in order to solve the characteristic coefficient corresponding to each load characteristic factor in each feature area of the system of the equations, it is necessary to obtain a preset coefficient correlation between respective characteristic coefficients, and then put it into the above system of the equations to facilitate coefficient solving.

In an embodiment of the present application, the preset coefficient correlation between respective characteristic coefficients specifically can be: the characteristic coefficients corresponding to the building roof proportion in different feature areas are equal; the characteristic coefficients corresponding to the water surface wetland proportion in different feature areas are equal; and there is a preset proportional relationship between the characteristic coefficient corresponding to the green space proportion and the characteristic coefficient corresponding to the road square proportion in the same feature area.

In related technologies, since the rainfall pollutants brought by rainfall in the same urban built-up area are basically the same, and the architectural styles in the same urban built-up area are basically the same, the water surface pollution loads and building roof pollution loads in respective feature area of the target area are basically the same, that is, k₄₁=k₄₂=k₄₃=k₄₄, k₂₁=k₂₂=k₂₃=k₂₄.

Due to urban planning and construction, the load equivalent of green spaces in the same urban built-up area is directly related to roads and squares. In related technologies, it can generally be set as k₃ᵢ=(0.15-0.3)k₁ᵢ.

In related technologies, Kₚᵢ is related to the area slope of the sub-catchment area. When the area slopes in different areas are basically the same, Kₚᵢ takes the same value of 1; and when different, an appropriate correction is made.

On the basis of the above, the factor value of each load characteristic factor and each proportional value corresponding to each feature area are obtained; and the coefficient parameter calculated based on the correlation of the above coefficients are obtained, and the coefficient parameter and the factor value are put into the above system of the equations for solving, to obtain the solved value of each characteristic coefficient.

Exemplarily, a system of load-factor relationship equations is constructed based on the benchmark runoff pollution load equivalent S and each load characteristic factor of four different feature areas in the preset year, and fitting was performed (fitting of each equation requires ≥4 sets of data). The results of the characteristic coefficients obtained are as follows:

$${S}_{1} = 59 79.4 {A}_{1} + 6 73.4 {B}_{1} + 11 36.1 {C}_{1} + 1 97.9 {D}_{1} ;$$

$${S}_{2} = 62 69.5 {A}_{2} + 673.4 {B}_{2} + 16 30.1 {C}_{2} + 1 97.9 {D}_{2} ;$$

$${S}_{3} = 19 46.5 {A}_{3} + 673.4 {B}_{3} + 4 47.7 {C}_{3} + 1 97.9 {D}_{3} ;$$

$${S}_{4} = 4 30.4 {A}_{4} + 6 73.4 {B}_{4} + 1 16.2 {C}_{4} + 1 97.9 {D}_{4} ;$$

where S₁, S₂, S₃, and S₄ respectively represent the benchmark runoff pollution loads of the benchmark sub-catchment areas characterized by the core commercial area, the residential area, the industrial cluster area, and the low impact development area; and Aᵢ, Bᵢ, Cᵢ, and Dᵢ respectively represent the load characteristic factors of respective benchmark sub-catchment areas.

S230, determining a runoff pollution load corresponding to the current sub-catchment area in the preset year based on the load characteristic factor and the characteristic coefficient.

In an embodiment of the present application, the target runoff pollution load can be understood as a runoff pollution load discharged through the target discharge outlet in the target area.

It can be explained that since each discharge outlet collects runoff pollution loads from a plurality of different sub-catchment areas, it is necessary to pre-calculate the runoff pollution load corresponding to each sub-catchment area corresponding to the target discharge outlet when calculating the target runoff pollution load corresponding to the target discharge outlet.

Specifically, for any sub-catchment area corresponding to the target discharge outlet, the load characteristic factor corresponding to the current sub-catchment area is obtained. Exemplarily, in this embodiment, taking the calculation of other 5 sub-catchment areas in the mentioned urban built-up area as an example, the following table shows information of the load characteristic factors of the 5 sub-catchment areas:

TABLE 2
Information table of load characteristic
factor of sub-catchment area

| | Sub-catchment | A′ᵢ | B′ᵢ | C′ᵢ | D′ᵢ | M |
|---|---|---|---|---|---|---|
| Feature area | area number | (%) | (%) | (%) | (%) | (hm²) |
| Core | 1 | 17 | 69 | 11 | 3 | 245 |
| commercial area | | | | | | |
| Residential area | 2 | 16 | 53 | 22 | 9 | 218 |
| Industrial | 3 | 45 | 49 | 5 | 1 | 239 |
| cluster area | | | | | | |
| Low impact | 4 | 21 | 31 | 34 | 14 | 267 |
| development area | | | | | | |
| Residential area | 5 | 20 | 51 | 23 | 6 | 262 |

Furthermore, the load characteristic factor and the characteristic coefficient calculated based on the above implementation method are substituted into the load-factor relationship equation constructed in the above implementation method to obtain the runoff pollution load corresponding to the current sub-catchment area.

Exemplarily, the expression for calculating the runoff pollution load of any sub-catchment area can be:

$${U}_{1} = {K}_{pi} \times ( {k}_{1 i} \times {A}_{i}^{′} + {k}_{2 i} \times {B}_{i}^{′} + {k}_{3 i} \times {C}_{i}^{′} + {k}_{4 i} \times {D}_{i}^{′} ) ;$$

where Ui represents the runoff pollution load of any sub-catchment area corresponding to the target discharge outlet; A′ᵢ, B′ᵢ, C′ᵢ, and D′ᵢ respectively represents the road square proportion, building roof proportion, green space proportion, and water surface wetland proportion in respective sub-catchment areas; k₁ᵢ, k₂ᵢ, k₃ᵢ, and k₄ᵢ represent the characteristic coefficients corresponding to the aforementioned respective proportional factors; and Kₚᵢ represents the slope factor.

Furthermore, since the above runoff pollution load is the pollution load per unit area in the sub-catchment area, in order to calculate the target runoff pollution load, it is also necessary to calculate the runoff pollution load of the sub-catchment area based on the area of the sub-catchment area.

Exemplarily, the expression for calculating the runoff pollution load can be:

$${L}_{i} = {U}_{i} \times {M}_{i} ;$$

where Lᵢ represents the runoff pollution load of any sub-catchment area; Uᵢ represents the pollution load per unit area in any sub-catchment area; and Mᵢ represents the catchment area of the sub-catchment area.

Exemplarily, runoff pollution load calculated for the five sub-catchment areas and information of the runoff pollution load are shown in the following table.

TABLE 3
Information table of runoff pollution load

| | Sub-catchment | Uᵢ | |
|---|---|---|---|
| Feature area | area number | (kg/hm²) | Lᵢ (kg) |
| Core commercial area | 1 | 1612.1 | 394952.4 |
| Residential area | 2 | 1736.4 | 378545.8 |
| Industrial cluster area | 3 | 1230.2 | 294030.9 |
| Low impact development area | 4 | 366.3 | 97816.7 |
| Residential area | 5 | 1984.1 | 519840.5 |

S240, determining a sum of runoff pollution loads of respective sub-catchment areas corresponding to the target discharge outlet in the preset year, performing a correction processing on the sum of runoff pollution loads based on a time correction factor between a target year and the preset year, to determine a target runoff pollution load corresponding to the target discharge outlet in the target year.

In an embodiment of the present application, since the target discharge outlet collects runoff pollutants from a plurality of preset sub-catchment areas, on the basis of obtaining the runoff pollution loads corresponding to respective sub-catchment areas of the target discharge outlet based on the above embodiment, the runoff pollution loads are summed up to obtain the sum of runoff pollution loads in the preset year.

Furthermore, since the characteristic coefficient is determined using data from the preset year, if a corresponding year when calculating the target runoff pollution load in the target area is another year, in order to improve accuracy of the data, a pre-determined time correction factor between the target year and the preset year can be used to correct the calculated sum of runoff pollution loads, so as to obtain the runoff pollution load in the target year, i.e., the target runoff pollution load of the target area in the target year. In an implementation, the correction factors for different years in the present application are related to rainfall intensity, rainfall amount, and annual pollution characteristics. If the target year is different from the preset year, the time correction factor is generally determined to be 0.8-1.2.

Certainly, in the above implementation, when calculating the runoff pollution loads corresponding to respective sub-catchment areas, the time correction factor can also be used in advance to correct the runoff pollution loads, and the target runoff pollution load can be obtained by summing up the corrected runoff pollution loads. The implementation order of the correction and summation in the embodiment of the present application is not specifically limited.

Exemplarily, the expression for determining the target runoff pollution load based on respective runoff pollution loads can be:

$$L = \sum {K}_{n} {L}_{i} ;$$

where L represents the target runoff pollution load; Kₙ represents the time correction factor; and Lᵢ represents the runoff pollution load of any sub-catchment area.

Exemplarily, on basis of the target area being an urban built-up area of a certain city in middle and lower reaches of the Yangtze River Basin, if the sub-catchment area corresponding to the target discharge outlet in the target area is the above sub-catchment areas No. 1 and No. 2, then, the statistical result of the target runoff pollution load (calculated as COD) of the target discharge outlet in the target year obtained based on the above expression is:

$$L = 394952.4 + 378545.8 = 77 3498.2 ( kg ) .$$

In the above technical solution, by using a benchmark runoff pollution load equivalent of a pre-selected benchmark catchment area in a target area in a preset year, a load characteristic factor that affects a pollution load formed when runoff pollutant of each sub-catchment areas converges at a catchment outlet and a corresponding characteristic coefficient are determined, and thus quick calculation of the runoff pollution load of each sub-catchment area, and then quick calculation of the runoff pollution load of the target discharge outlet in the target area are achieved. This avoids the technical problems that it is difficult to achieve the timeliness and accuracy requirements of fast calculation for the calculation result due to a large amount of monitoring data, repeated monitoring, large error of monitoring randomness, and long cycle of load calculation, etc.; and this achieves improvement of the efficiency and accuracy of the calculation result of the runoff pollution load.

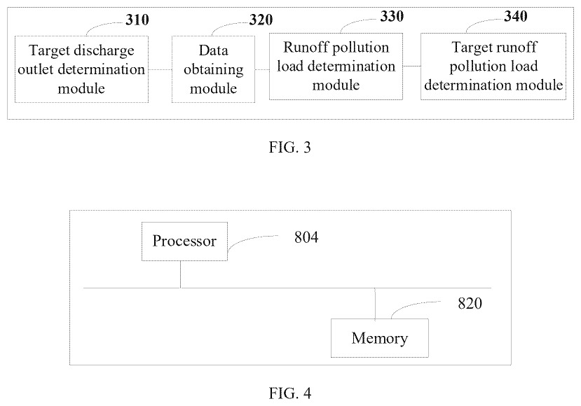

FIG. 3 is a schematic structural diagram of a calculation apparatus of a runoff pollution load provided in an embodiment of the present application. Referring to FIG. 3, the apparatus includes: a target discharge outlet determination module 310, a data obtaining module 320, a runoff pollution load determination module 330, and a target runoff pollution load determination module 340; where,
the target discharge outlet determination module 310 is configured to determine a target discharge outlet of a to-be-calculated runoff pollution load in a target area; where the target area is consisting of a plurality of feature areas with different area related features, the feature area is consisting of a plurality of sub-catchment areas, the target area includes a plurality of discharge outlets, and each discharge outlet collects runoff pollution loads from different sub-catchment areas;
the data obtaining module 320 is configured to, for any sub-catchment area corresponding to the target discharge outlet, obtain a load characteristic factor corresponding to a current sub-catchment area and a characteristic coefficient based on the load characteristic factor; where the load characteristic factor is a factor that affects a pollution load formed when a runoff pollutant of each sub-catchment area converges at a catchment outlet, and the characteristic coefficient is determined based on load characteristic factors respectively corresponding to a plurality of preset sub-catchment areas in the target area and a runoff pollution load equivalent in a preset year;
the runoff pollution load determination module 330 is configured to determine a runoff pollution load of the current sub-catchment area in the preset year based on the load characteristic factor and the characteristic coefficient; and
the target runoff pollution load determination module 340 is configured to determine a sum of runoff pollution loads of respective sub-catchment areas corresponding to the target discharge outlet in the preset year, and perform a correction processing on the sum of runoff pollution loads based on a time correction factor between a target year and the preset year, to determine a target runoff pollution load of the target discharge outlet in the target year.

In an implementation, the apparatus further includes:
a feature area determination unit, configured to, before determining the target discharge outlet of the to-be-calculated runoff pollution load in the target area, obtain area related feature data that affects the runoff pollution loads within different areas in the target area, and perform a functional area division on the target area based on the area related feature data to obtain a plurality of feature areas corresponding to the target area; and
a sub-catchment area determination unit, configured to, for any feature area, perform a catchment area division on a current feature area based on a rainfall catchment range to obtain a plurality of sub-catchment areas corresponding to the current feature area.

In an implementation, the feature area includes a benchmark sub-catchment area and other sub-catchment areas;
correspondingly, the data obtaining module 320 includes:
a benchmark runoff pollution load equivalent determination sub-module, configured to, for any feature area, determine the benchmark sub-catchment area in a current feature area, obtain runoff pollution monitoring data of the benchmark sub-catchment area in the preset year, and determine a benchmark runoff pollution load equivalent of the benchmark sub-catchment area in the preset year based on the runoff pollution monitoring data; and
a characteristic coefficient determination sub-module, configured to obtain a benchmark load characteristic factor of each benchmark sub-catchment area corresponding to each feature area, and based on each benchmark load characteristic factor and each benchmark runoff pollution load equivalent, determine the characteristic coefficient corresponding to the load characteristic factor when calculating the runoff pollution load based on the load characteristic factor.

In an implementation, the benchmark runoff pollution load equivalent determination sub-module includes:
a benchmark runoff pollution load equivalent determination unit, configured to obtain a preset runoff pollution load statistical algorithm, and perform a statistical processing of runoff pollution load per unit area on the benchmark sub-catchment area based on the runoff pollution load statistical algorithm and the runoff pollution monitoring data, to determine a benchmark runoff pollution load equivalent of the benchmark sub-catchment area in a preset year.

In an implementation, the characteristic coefficient determination sub-module includes:
a load-factor relationship equation determination unit, configured to, for any feature area, establish a load-factor relationship equation between the benchmark load characteristic factor and the benchmark runoff pollution load equivalent in the current feature area; and
a characteristic coefficient determination unit, configured to construct a system of load-factor relationship equations based on the load-factor relationship equations corresponding to respective feature areas, and determine the characteristic coefficient based on a preset coefficient correlation between the system of load-factor relationship equations and each characteristic coefficient.

In an implementation, the load characteristic factor includes a road square proportion, a building roof proportion, a green space proportion, a water surface wetland proportion and a terrain slope factor.
correspondingly, the load-factor relationship equation includes:

$${S}_{i} = {K}_{pi} \times ( {k}_{1 i} {A}_{i} + {k}_{2 i} {B}_{i} + {k}_{3 i} {C}_{i} + {k}_{4 i} {D}_{i} ) ;$$

where Sᵢ represents the benchmark runoff pollution load equivalent of the benchmark sub-catchment area in any feature area; Aᵢ represents the road square proportion; Bᵢ represents the building roof proportion; Cᵢ represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.

In an implementation, the coefficient correlation includes: the characteristic coefficients corresponding to the building roof proportion in different feature areas are equal; the characteristic coefficients corresponding to the water surface wetland proportion in different feature areas are equal; and there is a preset proportional relationship between the characteristic coefficient corresponding to the green space proportion and the characteristic coefficient corresponding to the road square proportion in the same feature area.

FIG. 4 is a schematic structural diagram of an electronic device provided in an embodiment of the present application. As shown in FIG. 4, the electronic device of this embodiment may include:
at least one processor 820; and a memory 804 connected in communication with the at least one processor 804;
where the memory 804 stores instructions that can be executed by the at least one processor 820, and the instructions, when executed by the at least one processor 820, cause a server to execute the method of any one of the above embodiments.

In an implementation, the memory 804 can be independent or integrated with the processor 820.

The implementation principle and technical effect of the electronic device provided in this embodiment can refer to the previous embodiments, and will not be repeated here.

An embodiment of the present application also provides a computer-readable storage medium storing computer-executable instructions which, when executed by a processor, implement the method of any one of the aforementioned embodiments.

An embodiment of the present application also provides a computer program product, including a computer program which, when executed by a processor, implements the method of any one of the aforementioned embodiments.

In the several embodiments provided in the present application, it should be understood that the disclosed devices and methods can be implemented in other ways. For example, the device embodiments described above are only illustrative. For example, the division of modules is only a logical function division. In practical implementation, there may be other division manners, such as multiple modules may be combined or integrated into another system, or some features can be ignored or not executed.

The integrated modules implemented in the form of software functional modules mentioned above can be stored in a computer-readable storage medium. The above software functional modules are stored in a storage medium, and include several instructions to enable a computer device (a personal computer, a server, or a network device, etc.) or a processor to perform some steps of the methods of various embodiments of the present application.

It should be understood that the above-mentioned processor can be a central processing unit (CPU), can also be other general-purpose processor, a digital signal processor (DSP), an application specific integrated circuit (ASIC), etc. The general-purpose processor can be a microprocessor or any conventional processor. The steps of the method disclosed in combination with the present application can be directly executed by a hardware processor, or by a combination of hardware and software modules in the processor. The memory may include a high-speed random access memory (RAM), as well as a non-volatile memory (NVM), such as at least one disk storage, and can also be a USB flash disk, a mobile hard disk, a read-only memory, a magnetic disk, or an optical disk.

The above-mentioned storage medium can be implemented by any type of volatile or non-volatile storage device or combination thereof, such as a static random-access memory (SRAM), an electrically-erasable programmable read-only memory (EEPROM), an erasable programmable read-only memory (EPROM), a programmable read-only memory (PROM), a read-only memory (ROM), a magnetic storage, a flash memory, a magnetic disk, or an optical disk. The storage medium can be any available medium that can be accessed by a general-purpose or special-purpose computer.

An exemplary storage medium is coupled to a processor, enabling the processor to read information from and write information to the storage medium. Certainly, the storage medium can also be a component of the processor. The processor and storage medium can be located in an application specific integrated circuit (ASIC). Certainly, the processor and storage medium can also exist as discrete components in a server or a main control device.

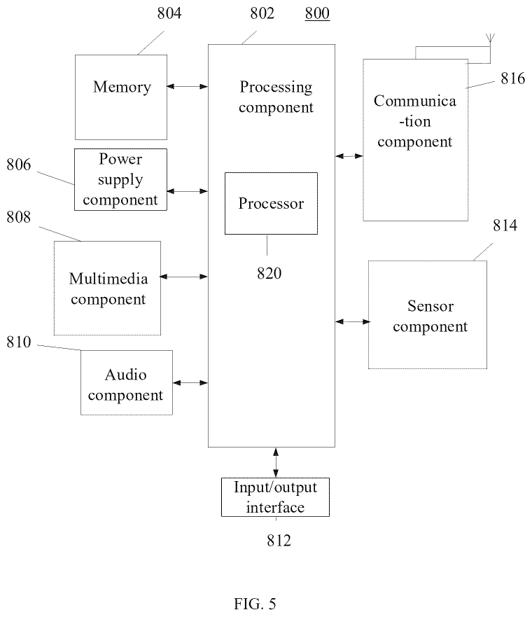

FIG. 5 is a block diagram of a terminal electronic device illustrated in an embodiment of the present application. The electronic device can be a mobile phone, computer, digital broadcasting terminal, message transceiving device, game console, tablet device, medical device, fitness device, personal digital assistant, etc.

The device 800 may include one or more of the following components: a processing component 802, a memory 804, a power supply component 806, a multimedia component 808, an audio component 810, an input/output interface 812, a sensor component 814, and a communication component 816.

The processing component 802 typically controls the overall operation of the device 800, such as operations associated with display, phone calls, data communication, camera operations, and recording operations. The processing component 802 may include one or more processors 820 to execute instructions to complete all or part of the steps of the methods described above. In addition, the processing component 802 may include one or more modules to facilitate interaction between the processing component 802 and other components. For example, the processing component 802 may include a multimedia module to facilitate interaction between the multimedia component 808 and the processing component 802.

The memory 804 is configured to store various types of data to support operations on the device 800. Examples of these data include instructions, contact data, phonebook data, messages, images, videos, etc., of any application or method operating on the device 800. The memory 804 can be implemented by any type of volatile or non-volatile storage device or combination thereof, such as a static random-access memory (SRAM), an electrically-erasable programmable read-only memory (EEPROM), an erasable programmable read-only memory (EPROM), a programmable read-only memory (PROM), a read-only memory (ROM), a magnetic storage, a flash memory, a magnetic disk, or an optical disk.

The power supply component 806 provides power for various components of the device 800. The power supply component 806 may include a power management system, one or more power sources, and other components associated with generating, managing, and distributing power for the device 800.

The multimedia component 808 includes a screen that provides an output interface between the device 800 and a user. In some embodiments, the screen may include a liquid crystal display (LCD) and a touch panel (TP). If the screen includes a touch panel, the screen can be implemented as a touch screen to receive an input signal from the user. The touch panel includes one or more touch sensors to sense touch, sliding, and gestures on the touch panel. The touch sensor can not only sense the boundary of a touch or sliding action, but also detect the duration and pressure associated with the touch or sliding operation. In some embodiments, the multimedia component 808 includes a front camera and/or a rear camera. When the device 800 is in an operation mode, such as a shooting mode or a video mode, the front camera and/or rear camera can receive external multimedia data. Each front camera and rear camera can be a fixed optical lens system or have a focal length and optical zoom capability.

The audio component 810 is configured to output and/or input an audio signal. For example, the audio component 810 includes a microphone (MIC), and when the device 800 is in an operation mode such as a call mode, a recording mode, and a voice recognition mode, the microphone is configured to receive an external audio signal. The received audio signal can be further stored in the memory 804 or sent via the communication component 816. In some embodiments, the audio component 810 also includes a speaker for outputting an audio signal.

The input/output interface 812 provides an interface between the processing component 802 and a peripheral interface module, and the peripheral interface module can be a keyboard, a click wheel, a button, etc. The button may include but is not limited to: a home button, a volume button, a start button, and a lock button.

The sensor component 814 includes one or more sensors for providing various aspects of state assessment for the device 800. For example, the sensor component 814 can detect an open/close status of the device 800, a relative positioning of components, such as display and keypad of the device 800. The sensor component 814 can also detect a change in position of device 800 or of a component of device 800, a presence or absence of user contact with the device 800, an orientation or acceleration/deceleration of the device 800, and a temperature change of the device 800. The sensor component 814 may include a proximity sensor configured to detect a presence of a nearby object without any physical contact. The sensor component 814 may also include a light sensor, such as a CMOS or CCD image sensor, for use in an imaging application. In some embodiments, the sensor component 814 may also include an acceleration sensor, a gyroscope sensor, a magnetic sensor, a pressure sensor, or a temperature sensor.

The communication component 816 is configured to facilitate wired or wireless communication between the device 800 and other devices. The device 800 can access a wireless network based on a communication standard, such as WiFi, 2G or 3G, or a combination thereof. In an exemplary embodiment, the communication component 816 receives a broadcast signal or broadcast related information from an external broadcast management system via a broadcast channel. In an exemplary embodiment, the communication component 816 further includes a near field communication (NFC) module to facilitate short-range communication. For example, the NFC module can be implemented based on a radio frequency identification (RFID) technology, an infrared data association (IrDA) technology, a ultra wideband (UWB) technology, a Bluetooth (BT) technology, and other technologies.

In an exemplary embodiment, the device 800 may be implemented by one or more application specific integrated circuits (ASIC), digital signal processors (DSPs), digital signal processing devices (DSPDs), programmable logic devices (PLDs), field programmable gate arrays (FPGAs), controllers, microcontrollers, microprocessors, or other electronic components, to perform the methods described above.

In an exemplary embodiment, a non-transitory computer-readable storage medium including instructions is also provided, such as the memory 804 including instructions, where the instructions can be executed by the processor 820 of the device 800 to implement the above methods. For example, the non-transitory computer-readable storage medium may be a ROM, a random access memory (RAM), a CD-ROM, a magnetic tape, a floppy disk, and an optical data storage device, etc.

The non-transitory computer-readable storage medium that, when the instructions in the storage medium are executed by a processor of a terminal electronic device, enables the terminal electronic device to perform the methods described above.

Those skilled in the art will easily come up with other embodiments of the present application after considering the specification and practicing the invention disclosed herein. The present application is intended to cover any variations, uses, or adaptive changes of the present application, and these variations, uses, or adaptive changes follow the general principles of the present application and include common knowledge or customary technical means in the art not disclosed in the present application. The specification and embodiments are only considered exemplary, and the true scope and spirit of the present application are indicated by the following claims.

It should be understood that the present application is not limited to the precise structures described above and shown in the accompanying drawings, and various modifications and changes can be made without departing from their scope. The scope of the present application is limited only by the appended claims.

What is claimed is:

1. A calculation method of a runoff pollution load, comprising:
determining a target discharge outlet of a to-be-calculated runoff pollution load in a target area, wherein the target area is consisting of a plurality of feature areas with different area related features, the feature area is consisting of a plurality of sub-catchment areas, the target area comprises a plurality of discharge outlets, and each discharge outlet collects runoff pollution loads from different sub-catchment areas;
for any sub-catchment area corresponding to the target discharge outlet, obtaining a load characteristic factor corresponding to a current sub-catchment area and a characteristic coefficient corresponding to the load characteristic factor when calculating the runoff pollution load based on the load characteristic factor, wherein the load characteristic factor is a factor that affects a pollution load formed when a runoff pollutant of each sub-catchment area converges at a catchment outlet, the characteristic coefficient is determined based on the load characteristic factors respectively corresponding to a plurality of preset sub-catchment areas in the target area and a runoff pollution load equivalent in a preset year;
determining a runoff pollution load of the current sub-catchment area in the preset year based on the load characteristic factor and the characteristic coefficient; and
determining a sum of runoff pollution loads of respective sub-catchment areas corresponding to the target discharge outlet in the preset year, and performing a correction processing on the sum of runoff pollution loads based on a time correction factor between a target year and the preset year, to determine a target runoff pollution load corresponding to the target discharge outlet in the target year.

2. The method according to claim 1, wherein before determining the target discharge outlet of the to-be-calculated runoff pollution load in the target area, the method further comprises:
obtaining area related feature data that affects the runoff pollution load within different areas in the target area, and performing a functional area division on the target area based on the area related feature data to obtain a plurality of feature areas corresponding to the target area; and
for any feature area, performing a catchment area division on a current feature area based on a rainfall catchment range to obtain a plurality of sub-catchment areas corresponding to the current feature area.

3. The method according to claim 1, wherein the feature area comprises a benchmark sub-catchment area and other sub-catchment areas;
correspondingly, determining the characteristic coefficient based on load characteristic factors respectively corresponding to the plurality of preset sub-catchment areas in the target area and the runoff pollution load equivalent in the preset year comprises:
for any feature area, determining the benchmark sub-catchment area in a current feature area, obtaining runoff pollution monitoring data of the benchmark sub-catchment area in the preset year, and determining a benchmark runoff pollution load equivalent of the benchmark sub-catchment area in the preset year based on the runoff pollution monitoring data; and
obtaining a benchmark load characteristic factor of each benchmark sub-catchment area corresponding to each feature area, and based on each benchmark load characteristic factor and each benchmark runoff pollution load equivalent, determining the characteristic coefficient corresponding to the load characteristic factor when calculating the runoff pollution load based on the load characteristic factor.

4. The method according to claim 3, wherein determining the benchmark runoff pollution load equivalent of the benchmark sub-catchment area in the preset year based on the runoff pollution monitoring data comprises:
obtaining a preset runoff pollution load statistical algorithm, and determining the benchmark runoff pollution load of the benchmark sub-catchment area based on the runoff pollution load statistical algorithm and the runoff pollution monitoring data; and
performing a statistical processing of runoff pollution load per unit area on the benchmark runoff pollution load, to determine the benchmark runoff pollution load equivalent corresponding to the benchmark sub-catchment area in the preset year.

5. The method according to claim 3, wherein based on each benchmark load characteristic factor and each benchmark runoff pollution load equivalent, determining the characteristic coefficient corresponding to the load characteristic factor when calculating the runoff pollution load based on the load characteristic factor comprises:
for any feature area, establishing a load-factor relationship equation between the benchmark load characteristic factor and the benchmark runoff pollution load equivalent in the current feature area; and
constructing a system of load-factor relationship equations based on the load-factor relationship equations corresponding to respective feature areas, and determining the characteristic coefficient based on a preset coefficient correlation between the system of load-factor relationship equations and each characteristic coefficient.

6. The method according to claim 5, wherein the load characteristic factor comprises a road square proportion, a building roof proportion, a green space proportion, a water surface wetland proportion and a terrain slope factor;
correspondingly, the load-factor relationship equation comprises:
$${S}_{i} = {K}_{pi} \times ( {k}_{1 i} {A}_{i} + {k}_{2 i} {B}_{i} + {k}_{3 i} {C}_{i} + {k}_{4 i} {D}_{i} ) ;$$
wherein Sᵢ represents the benchmark runoff pollution load equivalent of the benchmark sub-catchment area in any feature area; Aᵢ represents the road square proportion; Bᵢ represents the building roof proportion; Cᵢ represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.

7. The method according to claim 6, wherein the coefficient correlation comprises: the characteristic coefficients corresponding to the building roof proportion in different feature areas are equal; the characteristic coefficients corresponding to the water surface wetland proportion in different feature areas are equal; and there is a preset proportional relationship between the characteristic coefficient corresponding to the green space proportion and the characteristic coefficient corresponding to the road square proportion in a same feature area.

8. A calculation apparatus of a runoff pollution load, comprising:
a processor and a memory connected in communication with the processor,
wherein the memory stores computer-executable instructions; and
the processor executes the computer-executable instructions to be enabled to:
determine a target discharge outlet of a to-be-calculated runoff pollution load in a target area, wherein the target area is consisting of a plurality of feature areas with different area related features, the feature area is consisting of a plurality of sub-catchment areas, the target area comprises a plurality of discharge outlets, and each discharge outlet collects runoff pollution loads from different sub-catchment areas;
for any sub-catchment area corresponding to the target discharge outlet, obtain a load characteristic factor corresponding to a current sub-catchment area and a characteristic coefficient corresponding to the load characteristic factor when calculating the runoff pollution load based on the load characteristic factor, wherein the load characteristic factor is a factor that affects a pollution load formed when a runoff pollutant of each sub-catchment area converges at a catchment outlet, and the characteristic coefficient is determined based on the load characteristic factors respectively corresponding to a plurality of preset sub-catchment areas in the target area and a runoff pollution load equivalent in a preset year;
determine a runoff pollution load of the current sub-catchment area in the preset year based on the load characteristic factor and the characteristic coefficient; and
determine a sum of runoff pollution loads of respective sub-catchment areas corresponding to the target discharge outlet in the preset year, and perform a correction processing on the sum of runoff pollution loads based on a time correction factor between a target year and the preset year, to determine a target runoff pollution load corresponding to the target discharge outlet in the target year.

9. The apparatus according to claim 8, wherein before determining the target discharge outlet of the to-be-calculated runoff pollution load in the target area, the processor is further enabled to:
obtain area related feature data that affects the runoff pollution load within different areas in the target area, and perform a functional area division on the target area based on the area related feature data to obtain a plurality of feature areas corresponding to the target area; and
for any feature area, perform a catchment area division on a current feature area based on a rainfall catchment range to obtain a plurality of sub-catchment areas corresponding to the current feature area.

10. The apparatus according to claim 8, wherein the feature area comprises a benchmark sub-catchment area and other sub-catchment areas;
correspondingly, the processor is specifically enabled to:
for any feature area, determine the benchmark sub-catchment area in a current feature area, obtain runoff pollution monitoring data of the benchmark sub-catchment area in the preset year, and determine a benchmark runoff pollution load equivalent of the benchmark sub-catchment area in the preset year based on the runoff pollution monitoring data; and
obtain a benchmark load characteristic factor of each benchmark sub-catchment area corresponding to each feature area, and based on each benchmark load characteristic factor and each benchmark runoff pollution load equivalent, determine the characteristic coefficient corresponding to the load characteristic factor when calculating the runoff pollution load based on the load characteristic factor.

11. The apparatus according to claim 10, wherein the processor is specifically enabled to:
obtain a preset runoff pollution load statistical algorithm, and determine the benchmark runoff pollution load of the benchmark sub-catchment area based on the runoff pollution load statistical algorithm and the runoff pollution monitoring data; and
perform a statistical processing of runoff pollution load per unit area on the benchmark runoff pollution load, to determine the benchmark runoff pollution load equivalent corresponding to the benchmark sub-catchment area in the preset year.

12. The apparatus according to claim 10, wherein the processor is specifically enabled to:
for any feature area, establish a load-factor relationship equation between the benchmark load characteristic factor and the benchmark runoff pollution load equivalent in the current feature area; and
construct a system of load-factor relationship equations based on the load-factor relationship equations corresponding to respective feature areas, and determine the characteristic coefficient based on a preset coefficient correlation between the system of load-factor relationship equations and each characteristic coefficient.

13. The apparatus according to claim 12, wherein the load characteristic factor comprises a road square proportion, a building roof proportion, a green space proportion, a water surface wetland proportion and a terrain slope factor;
correspondingly, the load-factor relationship equation comprises:
$$Si = Kpi \times ( k 1 i Ai + k 2 i Bi + k 3 i Ci + k 4 i Di ) ;$$
wherein Sᵢ represents the benchmark runoff pollution load equivalent of the benchmark sub-catchment area in any feature area; Aᵢ represents the road square proportion; Bᵢ represents the building roof proportion; Cᵢ represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.

14. The apparatus according to claim 13, wherein the coefficient correlation comprises: the characteristic coefficients corresponding to the building roof proportion in different feature areas are equal; the characteristic coefficients corresponding to the water surface wetland proportion in different feature areas are equal; and there is a preset proportional relationship between the characteristic coefficient corresponding to the green space proportion and the characteristic coefficient corresponding to the road square proportion in a same feature area.

15. A non-transitory computer-readable storage medium, storing computer-executable instructions which, when executed by a processor, are caused to implement the following steps:
determining a target discharge outlet of a to-be-calculated runoff pollution load in a target area, wherein the target area is consisting of a plurality of feature areas with different area related features, the feature area is consisting of a plurality of sub-catchment areas, the target area comprises a plurality of discharge outlets, and each discharge outlet collects runoff pollution loads from different sub-catchment areas;
for any sub-catchment area corresponding to the target discharge outlet, obtaining a load characteristic factor corresponding to a current sub-catchment area and a characteristic coefficient corresponding to the load characteristic factor when calculating the runoff pollution load based on the load characteristic factor, wherein the load characteristic factor is a factor that affects a pollution load formed when a runoff pollutant of each sub-catchment area converges at a catchment outlet, and the characteristic coefficient is determined based on the load characteristic factors respectively corresponding to a plurality of preset sub-catchment areas in the target area and a runoff pollution load equivalent in a preset year;
determining a runoff pollution load of the current sub-catchment area in the preset year based on the load characteristic factor and the characteristic coefficient; and
determining a sum of runoff pollution loads of respective sub-catchment areas corresponding to the target discharge outlet in the preset year, and performing a correction processing on the sum of runoff pollution loads based on a time correction factor between a target year and the preset year, to determine a target runoff pollution load corresponding to the target discharge outlet in the target year.

16. The non-transitory computer readable storage medium according to claim 15, wherein before determining the target discharge outlet of the to-be-calculated runoff pollution load in the target area, when the computer-executable instructions are executed by the processor, the processor is further enabled to:
obtain area related feature data that affects the runoff pollution load within different areas in the target area, and perform a functional area division on the target area based on the area related feature data to obtain a plurality of feature areas corresponding to the target area; and
for any feature area, perform a catchment area division on a current feature area based on a rainfall catchment range to obtain a plurality of sub-catchment areas corresponding to the current feature area.

17. The non-transitory computer readable storage medium according to claim 15, wherein the feature area comprises a benchmark sub-catchment area and other sub-catchment areas;
correspondingly, when the computer-executable instructions are executed by the processor, the processor is specifically enabled to:
for any feature area, determine the benchmark sub-catchment area in a current feature area, obtaining runoff pollution monitoring data of the benchmark sub-catchment area in the preset year, and determine a benchmark runoff pollution load equivalent of the benchmark sub-catchment area in the preset year based on the runoff pollution monitoring data; and
obtain a benchmark load characteristic factor of each benchmark sub-catchment area corresponding to each feature area, and based on each benchmark load characteristic factor and each benchmark runoff pollution load equivalent, determine the characteristic coefficient corresponding to the load characteristic factor when calculating the runoff pollution load based on the load characteristic factor.

18. The non-transitory computer readable storage medium according to claim 17, wherein when the computer-executable instructions are executed by the processor, the processor is specifically enabled to:
obtain a preset runoff pollution load statistical algorithm, and determine the benchmark runoff pollution load of the benchmark sub-catchment area based on the runoff pollution load statistical algorithm and the runoff pollution monitoring data; and
perform a statistical processing of runoff pollution load per unit area on the benchmark runoff pollution load, to determine the benchmark runoff pollution load equivalent corresponding to the benchmark sub-catchment area in the preset year.

19. The non-transitory computer readable storage medium according to claim 17, wherein when the computer-executable instructions are executed by the processor, the processor is specifically enabled to:
for any feature area, establish a load-factor relationship equation between the benchmark load characteristic factor and the benchmark runoff pollution load equivalent in the current feature area; and
construct a system of load-factor relationship equations based on the load-factor relationship equations corresponding to respective feature areas, and determine the characteristic coefficient based on a preset coefficient correlation between the system of load-factor relationship equations and each characteristic coefficient.

20. The non-transitory computer readable storage medium according to claim 19, wherein the load characteristic factor comprises a road square proportion, a building roof proportion, a green space proportion, a water surface wetland proportion and a terrain slope factor;
correspondingly, the load-factor relationship equation comprises:
$${S}_{i} = {K}_{pi} \times ( {k}_{1 i} {A}_{i} + {k}_{2 i} {B}_{i} + {k}_{3 i} {C}_{i} + {k}_{4 i} {D}_{i} ) ;$$
wherein Sᵢ represents the benchmark runoff pollution load equivalent of the benchmark sub-catchment area in any feature area; Aᵢ represents the road square proportion; Bᵢ represents the building roof proportion; Cᵢ represents the green space proportion; Dᵢ represents the water surface wetland proportion; Kₚᵢ represents the terrain slope factor; k₁ᵢ represents the characteristic coefficient corresponding to the road square proportion; k₂ᵢ represents the characteristic coefficient corresponding to the building roof proportion; k₃ᵢ represents the characteristic coefficient corresponding to the green space proportion; and k₄ᵢ represents the characteristic coefficient corresponding to the water surface wetland proportion.
